(19) United States
(12) Patent Application Publication
(10) Pub. No.: US 2006/0264029 A1
(43) Pub. Date: Nov. 23, 2006

(54) Low inductance via structures

(75) Inventors: John Heck, Berkeley, CA (US); Qing Ma, San Jose, CA (US)

Correspondence Address: CAVEN & AGHEVLI;c/o PORTFOLIOIP, P.O. BOX 52050, MINNEAPOLIS, MN, 55402, US

(73) Assignee: Intel Corporation

(21) Appl. No.: 11/135,112

(22) Filed: May 23, 2005

(51) Int. Cl. H01L 21/4763; H01L 23/48

(52) U.S. Cl. 438/622; 257/774

(57) ABSTRACT

In one embodiment, a method for forming a semiconductor device, comprises forming a first aperture and a second aperture in a first surface of the substrate, the first and second apertures being coaxial; forming, in the first aperture, a first conductive path between the first surface of the substrate and a second surface of the substrate; and forming, in the second aperture, a second conductive path between the first surface of the substrate and a second surface of the substrate.

### BACKGROUND

Through silicon via structures provide an electrical connection between a conductor on a first layer of a semiconductor device and a conductor on a second layer of a semiconductor device. The first and second layers of the semiconductor device may be separated by a dielectric, and/or by a substrate material. Semiconductor devices that incorporate via structures may be used in a variety of applications, including radio frequency (RF) applications.

### BRIEF DESCRIPTION OF DRAWINGS

The detailed description is described with reference to the accompanying figures.

FIG. 1 is a flowchart illustrating operations in a method for fabricating a semiconductor device including low inductance via structures in accordance with an embodiment.

FIGS. 2A-2G are cross-sectional views illustrating a method for fabricating a semiconductor device including low inductance via structures in accordance with an embodiment.

FIG. 3A is a schematic plan view of a semiconductor device including a low inductance via structure in accordance with an embodiment.

FIG. 3B is a schematic cross-sectional view of the semiconductor device of FIG. 3A.

FIG. 4A is a schematic plan view of a semiconductor device including a low inductance via structure in accordance with an embodiment.

FIG. 4B is a schematic cross-sectional view of the semiconductor device of FIG. 4A.

FIG. 5 is a schematic illustration of a wireless telephone in accordance with one embodiment.

### DETAILED DESCRIPTION

Described herein are examples of low inductance via structures that may be incorporate into, e.g., in a semiconductor device, and techniques to make via structures. In the following description, numerous specific details are set forth to provide a thorough understanding of various embodiments. However, it will be understood by those skilled in the art that the various embodiments may be practiced without the specific details. In other instances, well-known methods, procedures, components, and circuits have not been described in detail so as not to obscure the particular embodiments.

In the following description, the term “semiconductor device” is used to identify discrete layers of material that form active semiconductor elements. A device, individually and in combination, can form many configurations, such as, but not limited to, a diode, a transistor, and a field effect transistor (FET), including devices found in electronic and optoelectronic devices. A device may also refer to one or more passive circuit elements, such as inductors, capacitors, or resistors, or a microelectromechanical system (MEMS) device, such as a cantilever switch.

Reference in the specification to “one embodiment” or “an embodiment” means that a particular feature, structure, or characteristic described in connection with the embodiment is included in at least an implementation. The appearances of the phrase “in one embodiment” in various places in the specification may or may not be all referring to the same embodiment.

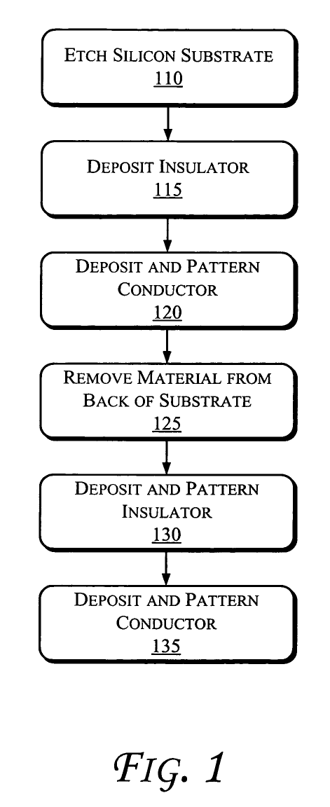

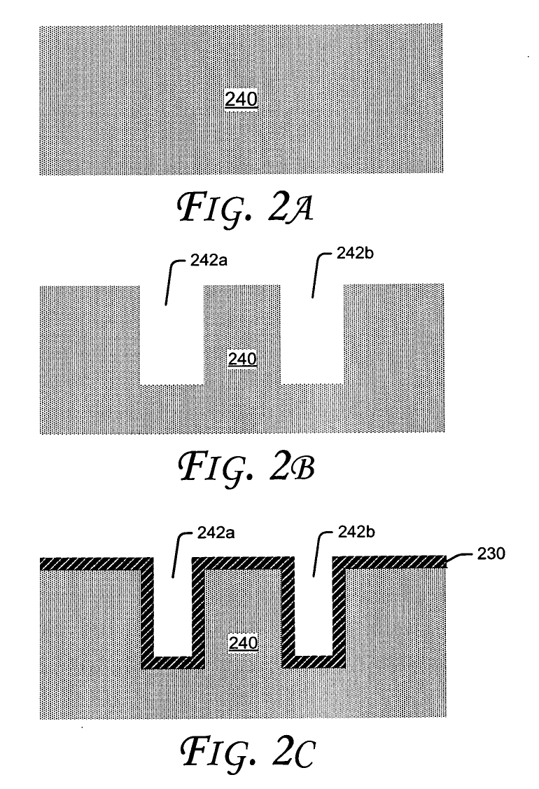

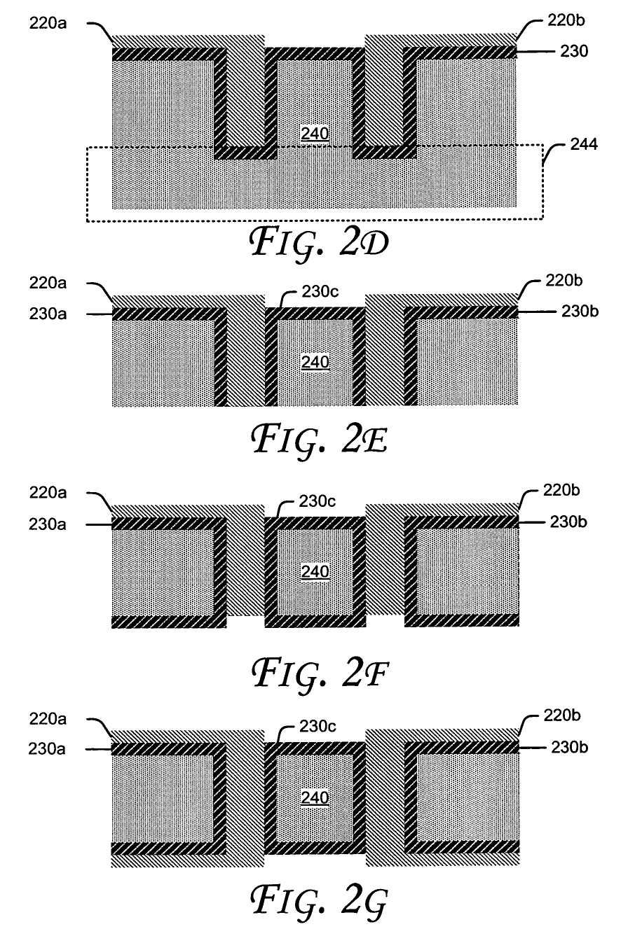

One embodiment of a technique to form low inductance via structures is illustrated with reference to FIG. 1 and FIGS. 2A-2G. FIG. 1 is a flowchart illustrating operations in a method for fabricating a semiconductor device including low inductance via structures in accordance with an embodiment. FIGS. 2A-2G are cross-sectional views illustrating various stages of a method for fabricating a semiconductor device including low inductance via structures in accordance with an embodiment.

FIG. 2A is a side-view of a semiconductor substrate 240. At operation 110 a pair of adjacent trenches 242a, 242b (FIG. 2B) are formed in a first surface of semiconductor substrate 240. A variety of processes may be used to form trenches 240a, 242b. In one embodiment trenches 242a, 242b are formed using an etching process such as, e.g., a mechanical etching process, a chemical etching process, a plasma etching process, a photo-chemical etching process, or the like.

The dimensions of trenches 242a, 242b are not important. In one embodiment trenches 242a, 242b measure approximately between 200 microns and 500 microns in depth, and may have a similar measurement in width.

At operation 115 an insulator is deposited on the surface of the substrate 240 in which the trenches 242a, 242b were formed. Referring to FIG. 2C, the layer of insulating material 230 is deposited to coat the surface of substrate 240, including the surfaces of trenches 242a, 242b. A variety of processes may be used to deposit the layer of insulating material 230. In one embodiment the layer of insulating material 230 may be deposited using a deposition process such as, e.g., chemical vapor deposition (CVD), electrodeposition, epitaxy, thermal oxidation, physical vapor deposition (PVD) casting, evaporation, sputter-coating, or the like.

The dimensions of insulating layer 230 are not important. In one embodiment insulating layer measures approximately between 5 microns and 100 microns in depth.

At operation 120 a layer of conducting material is deposited on the layer of insulating material 230 and is patterned to form a first conductor 220a and a second conductor 220b. Referring to FIG. 2D, the first conductor 220a covers portions of the insulating layer 230 and fills at least a portion of trench 242a. Similarly, second conductor 220b covers portions of the insulating layer 230 and fills at least a portion of trench 242b. The thickness of the layer of conductive material is not important. In one embodiment the layer of conductive material measures approximately between 5 microns and 100 microns in thickness. The portion of conductive layer that fills the trenches 242a, 242b is, of course, much thicker than the rest.

A variety of processes may be used to deposit the layer of conducting material. The layer of conductive material may be deposited using any of the aforementioned deposition techniques. Similarly, a variety of processes may be used to form conductors 220a, 220b is not critical. In one embodiment the layer of conductive material may be formed using any of the aforementioned selective etching techniques.

At operation 125 material is removed from the back surface of the substrate 240. As used herein, the term “back” refers to the surface of the substrate opposite the surface in which trenches 242a, 242b were formed. This nomenclature is arbitrary. In one embodiment a sufficient quantity of material is removed from the back surface of the substrate 240 to expose the conductors 220a, 220b that were filled in trenches 242a, 242b, respectively. Referring to FIG. 2D, in one embodiment an amount corresponding to the material within dashed box 244 may be removed. In the embodiment depicted in FIG. 2E portions of the layer of insulating material 230 are removed, resulting in three electrically isolated layers of insulating material labeled 230a, 230b, and 230c.

A variety of processes may be used to remove material from the back surface of the substrate 240 is not critical. In one embodiment material is removed using a suitable grinding process. Alternately, one or more of the aforementioned etching processes may be used to remove material from the back surface of substrate 240.

At operation 130 a layer of insulating material is deposited onto the back surface and patterned to expose the conductors 220a, 220b that were filled in trenches 242a, 242b, respectively. Referring to FIG. 2F, the deposition and etching operations form three electrically isolated insulators, identified by 230a, 230b, and 230c. Any of the aforementioned deposition and patterning techniques may be used in operation 130.

At operation 135 a layer of conductive material is deposited onto the insulators 230a, 230b, 230c (FIG. 2F) on the back surface of substrate 240 and the exposed surfaces of conductors 220a, 220b that were filled in trenches 242a, 242b, respectively. Referring to FIG. 20, the layer of conductive material is patterned to maintain the separation between the conductors 220a and 220b. In the embodiment depicted in FIG. 2G the conductive layer is patterned to expose the insulator 230c. In an alternate embodiment, portions of insulator 230c may remain covered by the layer of conductive material. Any of the aforementioned deposition and patterning techniques may be used in operation 135.

Operations 110-135 permit the fabrication of conductive pathways that traverse the front surface of substrate 240, traverse a cross-section of substrate 240, and traverse the back surface of substrate 240. The portion of the conductive pathway that traverses the cross-section of substrate 240 is referred to as a via. Hence, operations 110-135 permit the construction of multi-layered semiconductor devices coupled by vias.

Operations 110-135 illustrate the construction of vias between front surface of substrate 240 and the back surface of substrate 240. The techniques of operations 110-135 may be used to construct any number of vias between the front surface of substrate 240 and the back surface of substrate 240. Further, the techniques illustrated in operation 110-135 may be extended to construct multi-layered semiconductor devices.

A variety of materials may be used to fabricate the semiconductor device. Semiconductor substrates may comprise silicon, silicon-germanium, germanium, glass, and the like. Insulating materials may comprise various oxides, nitrides, polymers, or the like. Conductors may comprise copper, gold, aluminum, various alloys thereof, and the like.

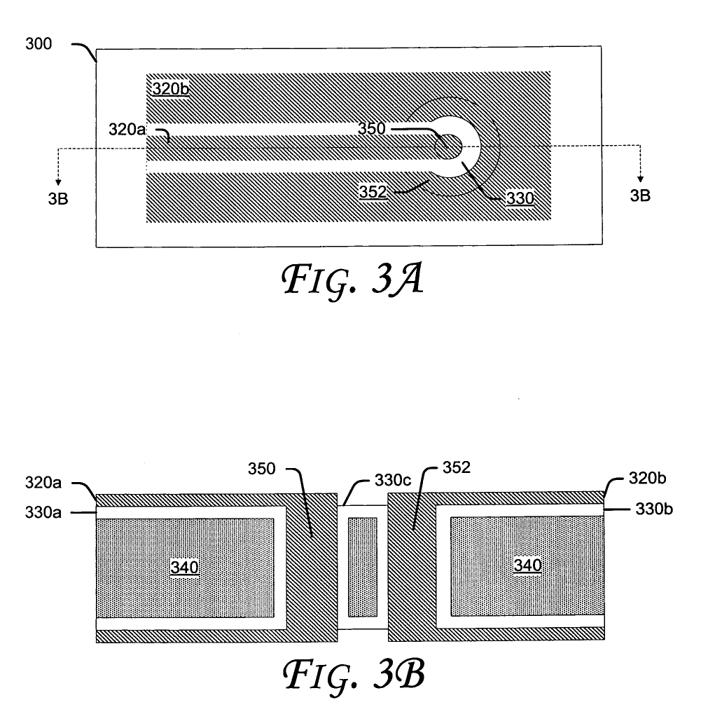

The techniques illustrated in FIGS. 1 and 2A-2G may be used to construct low inductance via structures. FIG. 3A is a schematic plan view of a semiconductor device 300 including a low inductance via structure in accordance with an embodiment. In one embodiment the semiconductor device depicted in FIG. 3A may include a coplanar waveguide. FIG. 3B is a schematic partial, cross-sectional sectional view of the semiconductor device 300 depicted in FIG. 3A. In one embodiment the semiconductor device 300 may include a coplanar waveguide. In another embodiment the semiconductor device 300 may include planar signal and ground lines coupled through via structures.

Referring to FIGS. 3A and 3B, semiconductor device 300 may include a signal conductor 320a that traverses a portion of the front of substrate 340 and a portion of the back of substrate 340. Signal conductor 320a traverses the cross-section of substrate 340 through via 350. Similarly, semiconductor device 300 includes a ground conductor 320b that traverses a portion of the front of substrate 340 and a portion of the back of substrate 340. Ground conductor 320b traverses the cross-section of substrate 340 through via 352. Insulator 330c in FIG. 3B corresponds to the portion of insulating layer 330 visible in FIG. 3A

In the embodiment depicted in FIGS. 3A-3B, via 350 and via 352 are substantially coaxial along an axis extending perpendicularly through substrate 340. As used herein, the term coaxial should not be construed in a strict geometric sense to require perfect alignment of the longitudinal axes of via 350 and via 352. Rather, the term coaxial should be construed to permit deviations between the longitudinal axes of via 350 and via 352, as may result from design constraints and/or manufacturing imperfections. Because signal conductor 320a and ground conductor 320b are substantially co-planar, via 352 cannot completely encircle via 350. Nevertheless, the coaxial via structure defined by via 350 and via 352 may provide a low inductance path between the front of substrate 340 and the back of substrate 340.

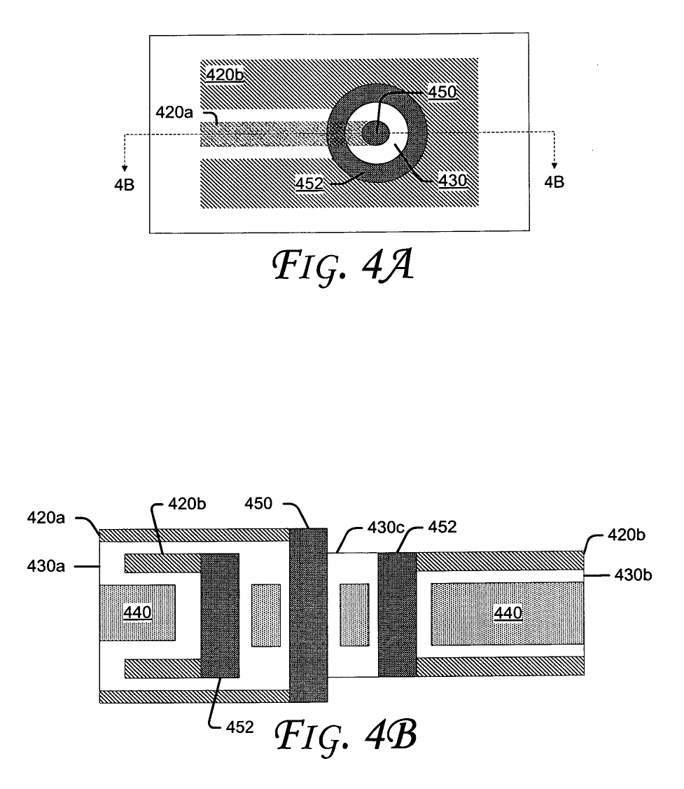

FIG. 4A is a schematic plan view of a semiconductor device 400 including a low inductance via structure in accordance with an embodiment. In one embodiment the semiconductor device depicted in FIG. 3A may include a coplanar waveguide. FIG. 4B is a schematic partial, cross-sectional view of the semiconductor device 400 depicted in FIG. 4A. In one embodiment the semiconductor device 400 may include a coplanar waveguide. In another embodiment the semiconductor device 400 may include planar signal and ground lines coupled through via structures.

Referring to FIGS. 4A and 4B, semiconductor device 400 includes a signal conductor 420a that traverses a portion of the front of substrate 440 and a portion of the back of substrate 440. Signal conductor 420a traverses the cross-section of substrate 440 through via 450. Similarly, semiconductor device 400 includes a ground conductor 420b that traverses a portion of the front of substrate 440 and a portion of the back of substrate 440. Ground conductor 420b traverses the cross-section of substrate 440 through via 452. Insulator 430c in FIG. 4B corresponds to the portion of insulating layer 430 visible in FIG. 4A

In the embodiment depicted in FIGS. 4A-4B, via 450 and via 452 are substantially coaxial along an axis extending perpendicularly through substrate 440. As used herein, the term coaxial should not be construed in a strict geometric sense to require perfect alignment of the longitudinal axes of via 450 and via 452. Rather, the term coaxial may be construed to permit deviations between the longitudinal axes of via 450 and via 452, e.g., as may result from design constraints and/or manufacturing imperfections. Referring to FIG. 4B, because signal conductor 420a resides in a plane that is above the plane in which ground conductor 420b resides, via 452 can completely encircle via 450. The coaxial via structure defined by via 450 and via 452 may provide a low inductance path between the front of substrate 440 and the back of substrate 440.

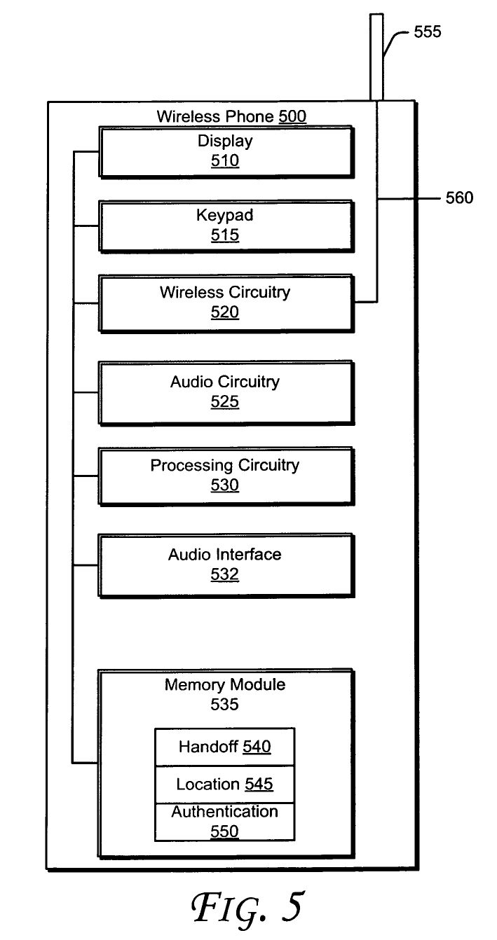

Semiconductor devices comprising low inductance vias as described herein may be used as circuit components in radio frequency (RF) transceiver applications such as, e.g., wireless telephones, and wireless networking adapters for computing devices. FIG. 5 is a schematic illustration of a wireless telephone 500 in accordance with one embodiment. Referring to FIG. 5, wireless telephone 500 includes a display 510, keypad 515, wireless circuitry 520, audio circuitry 525, and processor 530. The processor 530 is coupled to a memory module 535. Wireless circuitry 520 is coupled to an antenna 555 by a suitable connection 560.

Wireless signals received by antenna 555 are processed by wireless circuitry 520, which may operate as an RF transceiver. Wireless circuitry 520 may include a receiver filter, a downconverter circuit, baseband filters, analog-to-digital-converters (ADCs), local oscillator circuits, and the like. Wireless circuitry 520 may further include a transmitter that comprises a power amplifier (PA) circuit, which is used to amplify a transmit signal to a level appropriate for transmission from antenna 555. Wireless circuitry 520 may support one or more frequency ranges. For example, unlicensed wireless signals may be sent at 900 MHz or in the frequency range between 2.4 GHz and 5 GHz.

Processing circuit 530 may include a baseband processor, which may comprise one or more microprocessors, application specific integrated circuits (ASICs), field programmable gate arrays (FPGAs), or other digital logic devices, and one or more supporting circuits, such as clocking/timing control circuits, input/output (I/O) interface circuits, and one or more memory devices, such as electrically erasable programmable read only memory (EEPROM) or FLASH memory, to store instructions and calibration data, etc., as needed or desired.

Processed wireless signals are converted to an audio signal by audio circuitry 525. Audio signals may be presented to a user by an audio interface 532 that includes a speaker, microphone, and/or other device. Audio signals received in audio interface 532 may be processed by the processor 530, audio circuitry 525, and wireless circuitry 520. Wireless signals are then sent to the antenna 555, where they are broadcast as RF signals.

The memory module 535 may include logic instructions for implementing various features or functions. For example, memory module 535 may include a handover module 540 to manage handoffs between base stations in a cellular network. Memory module 535 may also include a location tracking module 545 that determines the current location of the wireless telephone 500. In addition, memory module 535 may include authentication module 550 to coordinate an authentication procedure for authenticating that the wireless telephone 500 is licensed for use within a network.

Thus, although embodiments have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. A method, comprising:
forming a first aperture and a second aperture in a first surface of the substrate, the first and second apertures being coaxial;
forming, in the first aperture, a first conductive path between the first surface of the substrate and a second surface of the substrate; and
forming, in the second aperture, a second conductive path between the first surface of the substrate and a second surface of the substrate.

2. The method of claim 1, wherein forming a first aperture and a second aperture in the substrate comprises:
forming a first trench and a second trench in a first surface of the substrate, first and second trenches being coaxial; and
removing portions of the second surface of the substrate.

3. The method of claim 1, wherein forming, in the first aperture, a first conductive path between the first surface of the substrate and a second surface of the substrate comprises:
forming a first trench in the first surface of the substrate;
forming a first layer of conductive material on the first surface, the layer of conductive material filling the first trench;
patterning the first layer of conductive material to form a first conductor on the first surface; and
removing portions of a second surface of the substrate to expose the conductive material in the first trench.

4. The method of claim 3, further comprising:
forming a second layer of conductive material on the second surface in electrical contact with the conductive material in the first trench;
patterning the second layer of conductive material to form a second conductor on the second surface.

5. The method of claim 1, wherein forming, in the second aperture, a second conductive path between the first surface of the substrate and a second surface of the substrate comprises:
forming a second trench in the first surface of the substrate;
forming a first layer of conductive material on the first surface, the layer of conductive material filling the second trench;
patterning the first layer of conductive material to form a third conductor on the first surface; and
removing portions of a second surface of the substrate to expose the conductive material in the second trench.

6. The method of claim 5, further comprising:
forming a second layer of conductive material on the second surface in electrical contact with the conductive material in the second trench;
patterning the second layer of conductive material to form a fourth conductor on the second surface.

7. A method, comprising:
forming coaxial trenches in a first surface of a substrate;
forming a first layer of insulating material on the first surface of the substrate;
forming a first layer of conductive material on the first layer of insulating material;
patterning the first layer of conductive material to form a first conductor and a second conductor;
removing portions of a second surface of the substrate to expose portions of the first layer of insulating material and the first layer of conductive material;
forming a second layer of insulating material on the second surface of the substrate;
forming a second layer of conductive material on the second layer of insulating material; and
patterning the second layer of conductive material to isolate a portion of the second layer that is in electrical communication with the first conductor a portion of the second layer that is in electrical communication with the second conductor.

8. The method of claim 7, wherein forming adjacent trenches on a first surface of a substrate comprises etching portions of the substrate material.

9. The method of claim 7, wherein forming a first layer of insulating material on the first surface of the substrate comprises depositing an insulating material on the first surface of the substrate.

10. The method of claim 7, wherein forming a first layer of conductive material on the first layer of insulating material comprises depositing a conductive material on the first surface of the substrate.

11. The method of claim 7, wherein patterning the first layer of conductive material to form a first conductor and a second conductor comprises selectively etching portions of the conductive material.

12. The method of claim 7, wherein removing portions of a second surface of the substrate to expose portions of the first layer of insulating material and the first layer of conductive material comprises grinding portions of the second surface of the substrate.

13. A semiconductor device, comprising:
a substrate;
a first via to couple a source conductor on a first surface of the substrate to a source conductor on a second surface of the substrate; and
a second via, coaxial with the first via, to couple a ground conductor on a first surface of the substrate to a ground conductor on a second surface of the substrate.

14. The semiconductor device of claim 13, wherein the source conductor on the first surface and the ground conductor on the first surface are coplanar.

15. The semiconductor device of claim 13, wherein the source conductor on the first surface resides in a first plane and the ground conductor on the first surface resides in a second plane.

16. The semiconductor device of claim 13, wherein the source conductor on the second surface and the ground conductor on the second surface are coplanar.

17. The semiconductor device of claim 13, wherein the source conductor on the second surface resides in a third plane and the ground conductor on the second surface resides in a fourth plane.

18. A wireless telephone, comprising:
an audio interface;
circuitry to receive wireless communication signals and to convert the wireless communication signals to audio signals presentable on the audio interface, the circuitry including a semiconductor device, comprising:
a substrate;
a first via to couple a source conductor on a first surface of the substrate to a source conductor on a second surface of the substrate; and
a second via, coaxial with the first via, to couple a ground conductor on a first surface of the substrate to a ground conductor on a second surface of the substrate.

19. The wireless telephone of claim 18, wherein the semiconductor device comprises a radio frequency transceiver, a receiver filter, a downconverter circuit, a baseband filter, an analog-to-digital-converter, a local oscillator circuit, or a power amplifier circuit.

20. The wireless telephone of claim 18, wherein the semiconductor device comprises a coaxial via.
